(19) United States
(12) Patent Application Publication
(10) Pub. No.: US 2025/0125309 A1
(43) Pub. Date: Apr. 17, 2025

(54) SEMICONDUCTOR DEVICE STRUCTURE WITH COMPRESSIBLE BONDS AND METHODS FOR FORMING THE SAME

(71) Applicant: Taiwan Semiconductor Manufacturing Company Limited, Hsinchu (TW)

(72) Inventors: Kai-Hsiang Yang, Hsinchu (TW); Chin-Fu Kao, Taipei (TW); Amram Eitan, Hsinchu (TW); Shu-Cheng Lin, Hsinchu (TW)

(21) Appl. No.: 18/484,541

(22) Filed: Oct. 11, 2023

(51) Int. Cl. H01L 25/065; H01L 23/00; H01L 25/00

(52) U.S. Cl. CPC H01L 25/0657; H01L 24/11; H01L 24/13; H01L 24/16; H01L 24/81; H01L 25/50; H01L 2224/11464; H01L 2224/13022; H01L 2224/13139; H01L 2224/13144; H01L 2224/13147; H01L 2224/13155; H01L 2224/13164; H01L 2224/13169; H01L 2224/16013; H01L 2224/16058; H01L 2224/16145; H01L 2224/8083; H01L 2225/06513; H01L 2924/01005; H01L 2924/01015; H01L 2924/01016; H01L 2924/01028; H01L 2924/01029; H01L 2924/01046; H01L 2924/01047; H01L 2924/01078; H01L 2924/01079; H01L 2924/04642; H01L 2924/05042; H01L 2924/05442; H01L 2924/05994

(57) ABSTRACT

Vertically stacked semiconductor devices and methods of fabrication thereof that include a first device structure bonded to a second device structure via bonding layers having compressible metal bonding structures. The compressible metal bonding structures may be fabricated using an electroless deposition (ED) process, and may be less dense with a greater degree of compressibility than equivalent materials deposited by related processes. Accordingly, mating pairs of metal bonding structures may have a degree of compliance that enables effective metal-to-metal contact during a subsequent bonding process. Recrystallization of the metal material during an annealing process may produce shrinkage of the metal material and the formation of void areas between the metal bonds and the surrounding dielectric layers, thereby reducing stress on the surrounding dielectric-to-dielectric interface. Accordingly, bonding defects may be minimized and the performance and yields of vertically stacked semiconductor devices may be improved.

### BACKGROUND

The semiconductor industry has grown due to continuous improvements in integration density of various electronic components (e.g., transistors, diodes, resistors, capacitors, etc.).

In addition to smaller electronic components, improvements to the packaging of components have been developed in an effort to provide smaller packages that occupy less area than previous packages. Example approaches include quad flat pack (QFP), pin grid array (PGA), ball grid array (BGA), flip chips (FC), three-dimensional integrated circuits (3DICs), wafer level packages (WLPs), package on package (POP), System on Chip (SoC) or System on Integrated Circuit (SoIC) devices. Some of these three-dimensional devices are prepared by placing chips over chips. These three-dimensional devices provide improved integration density and other advantages because of the decreased length of interconnects between the stacked chips. However, there are many challenges related to three-dimensional devices.

### BRIEF DESCRIPTION OF THE DRAWINGS

Aspects of this disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a vertical cross-sectional view illustrating an intermediate first device structure according to various embodiments of the present disclosure.

FIG. 2 is a vertical cross-sectional view of the intermediate first device structure after a first dielectric layer formed over the first interconnect structure according to various embodiments of the present disclosure.

FIG. 3 is a vertical cross-sectional view of the intermediate first device structure after forming a patterned mask over the upper surface of the first dielectric layer according to various embodiments of the present disclosure.

FIG. 4 is a vertical cross-sectional view of the intermediate first device structure after forming a plurality of openings in the first dielectric layer according to various embodiments of the present disclosure.

FIG. 5 is a vertical cross-sectional view of the intermediate first device structure after forming a plurality of first metal bonding structures formed within the openings in the first dielectric layer according to various embodiments of the present disclosure.

FIG. 6 is a vertical cross-sectional view of the intermediate first device structure after a second device structure is aligned over the first device structure according to an embodiment of the present disclosure.

FIG. 7 is a vertical cross-sectional view illustrating the second device structure placed onto the first device structure according to various embodiments of the present disclosure.

FIG. 8 is a vertical cross-sectional view illustrating a vertically stacked semiconductor device following an annealing process that bonds the first metal bonding structures of the first bonding layer to the second metal bonding structures of the second bonding layer according to various embodiments of the present disclosure.

FIG. 9A is a vertical cross-sectional view illustrating a second device structure placed onto a first device structure according to another embodiment of the present disclosure.

FIG. 9B is a vertical cross-sectional view illustrating a vertically stacked semiconductor device following an annealing process that bonds the first metal bonding structures of the first bonding layer to the second metal bonding structures of the second bonding layer according to various embodiments of the present disclosure.

FIG. 10A is a vertical cross-sectional view illustrating a second device structure placed onto a first device structure according to another embodiment of the present disclosure.

FIG. 10B is a vertical cross-sectional view illustrating a vertically stacked semiconductor device following an annealing process that bonds the first metal bonding structures of the first bonding layer to the second metal bonding structures of the second bonding layer according to various embodiments of the present disclosure.

FIG. 11 is a vertical cross-sectional view illustrating a first device structure including a first interconnect structure and a first dielectric layer formed over the first interconnect structure according to various embodiments of the present disclosure.

FIG. 12 is a vertical cross-sectional view of the intermediate first device structure after forming a plurality of openings in the first dielectric layer according to various embodiments of the present disclosure.

FIG. 13 is a vertical cross-sectional view of the intermediate first device structure after forming a plurality of first metal bonding structures within the openings in the first dielectric layer according to various embodiments of the present disclosure.

FIG. 14 is a vertical cross-sectional view illustrating a second device structure placed onto the first device structure according to various embodiments of the present disclosure.

FIG. 15 is a vertical cross-sectional view illustrating a vertically stacked semiconductor device following an annealing process that bonds the first metal bonding structures of the first bonding layer to the second metal bonding structures of the second bonding layer according to various embodiments of the present disclosure.

FIG. 16 is a flowchart illustrating a method of fabricating a vertically stacked semiconductor device according to an embodiment of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Unless explicitly stated otherwise, each element having the same reference numeral is presumed to have the same material composition and to have a thickness within a same thickness range.

Various embodiments disclosed herein are directed to semiconductor devices, and specifically to vertically stacked semiconductor devices that include at least one semiconductor die stacked over and bonded to a second device structure, which may be, for example, another semiconductor die or a semiconductor wafer. The at least one semiconductor die may be vertically stacked in a configuration such as a system on integrated chip (SoIC), chip on wafer on substrate (CoWoS), chip on wafer (CoW), etc. Such vertically stacked semiconductor devices may increase the density of devices that may occupy a given planar area or “footprint.”

Semiconductor dies may include a semiconductor material substrate, such as a silicon substrate, having a number of circuit components and elements formed on and/or within the semiconductor material. Semiconductor dies are typically fabricated by sequentially depositing insulating or dielectric layers, conductive layers, and semiconductive layers of material over a semiconductor substrate (e.g., a wafer), patterning the various material layers using lithography to form integrated circuits, and separating individual dies from the substrate such as by sawing between the integrated circuits along scribe lines.

A vertically stacked semiconductor device may be formed by placing a first semiconductor device structure onto a second semiconductor device structure in a “face down” configuration such that integrated circuit components formed on a first (i.e., front) side of a semiconductor substrate of the first semiconductor device structure face towards integrated circuit components formed on the front side of a semiconductor substrate of the second semiconductor device structure. The first semiconductor device structure and the second semiconductor device structure may be, for example, semiconductor dies, semiconductor wafers, or combinations thereof (e.g., a semiconductor die on a semiconductor wafer). A bonding process may be used to bond bonding features on the first semiconductor device structure to corresponding bonding features on the second semiconductor device structure.

In some embodiments, a direct bonding technique, such as metal-to-metal (M-M) and dielectric-to-dielectric (D-D) bonding technique, may be used to bond the first semiconductor device structure and the second semiconductor device structure to form a vertically stacked semiconductor device. In such bonding techniques, bonding layers including an array of metal bonding pads surrounded by a dielectric material may be formed on both the first semiconductor device structure and the second semiconductor device structure. The bonding layer on the first semiconductor device structure may be aligned over the corresponding bonding layer on the second semiconductor device structure, and the two bonding layers may be brought into contact with one another. This may result in a chemical pre-bond between the dielectric material of the respective bonding layers. An annealing process may then be performed to promote bonding of the metal bonding pads of the respective bonding layers, thereby producing metal bonds extending between the first semiconductor device structure and the second semiconductor device structure.

In many cases, the process window for performing a successful direct metal-to-metal (M-M) and dielectric-to-dielectric (D-D) bond between two semiconductor device structures may be relatively small, particularly as the size of the metal bonding pads and the spacing (i.e., pitch) between the bonding pads in the respective bonding layers is reduced in order to provide higher performance and greater energy efficiency in vertically stacked semiconductor devices. One important parameter during the bonding process is the amount of “dishing” of the metal bonding pads in the bonding layers. “Dishing” may be defined as the difference in height between the lowest point of the metal bonding pad (typically in the center of the pad) and the highest point of the dielectric material laterally surrounding the bonding pad. An excessive amount of dishing may result in defective bonds (i.e., metal disconnection defects) occurring between the metal pads in the respective bonding layers. In addition, in some cases, expansion of the metal bonding pads during the annealing process may produce high stress at the metal-to-metal interface. This stress may result in delamination defects in the surrounding dielectric-to-dielectric interface. Metal disconnection defects and/or dielectric delamination defects should be avoided as they may negatively affect the performance of vertically stacked semiconductor devices and may reduce device yields.

In order to improve the reliability of the bonding between a first device structure and a second device structure in a vertically-stacked semiconductor device, various embodiments disclosed herein may include bonding layers having compressible metal bonding structures. In various embodiments, the compressible metal bonding structures may be fabricated using an electroless deposition (ED) process. Electroless deposition is a chemical deposition process that utilizes oxidation-reduction (i.e., redox) reactions to reduce metal ions from a chemical solution onto a target surface, resulting in the deposition of a metal material onto the surface. Metal materials deposited via an ED process may be less dense and may have a greater degree of compressibility (i.e., a lower Young's modulus) than equivalent materials deposited by related processes, such as via electroplating. Accordingly, mating pairs of metal bonding structures formed by ED may have a degree of compliance that may enable effective metal-to-metal contact during a subsequent bonding process. In addition, recrystallization of the electroless-deposited metal material the during the annealing process may result in shrinkage of the metal material and the formation of void areas between the metal bonds and the surrounding dielectric layers, thereby reducing stress on the surrounding dielectric-to-dielectric interface. Accordingly, bonding defects, such as metal disconnection defects and/or dielectric delamination defects, may be minimized and the performance and yields of vertically-stacked semiconductor devices may be improved.

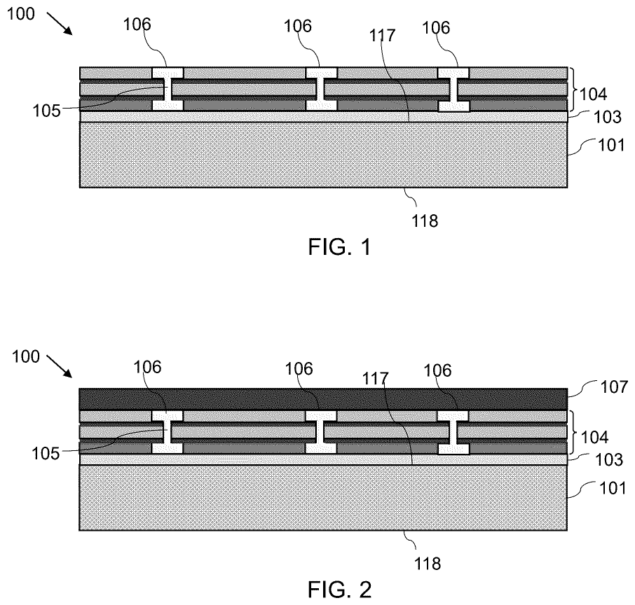

FIGS. 1-8 are sequential vertical cross-sectional views illustrating the intermediate structures during a process of fabricating a vertically stacked semiconductor device according to various embodiments of the present disclosure. FIG. 1 is a vertical cross-sectional view illustrating a first device structure 100 according to various embodiments of the present disclosure. The first device structure 100 may include a first semiconductor substrate 101 that may include an elementary semiconductor such as silicon or germanium and/or a compound semiconductor such as silicon germanium, silicon carbide, gallium arsenic, indium arsenide, gallium nitride, or indium phosphide, or combinations of the same. Other semiconductor substrate materials are within the contemplated scope of disclosure. In some embodiments, the first semiconductor substrate 101 may be a semiconductor-on-insulator (SOI) substrate.

The first semiconductor substrate 101 may include a first major surface (i.e., a front side surface 117) and a second major surface (i.e., a backside surface 118). In some embodiments, a thickness of the first semiconductor substrate 101 between the front side surface 117 and the backside surface 118 may be between about 100 μm and about 800 μm, although a semiconductor substrate 101 having a greater or lesser thickness may also be utilized. A first device level 103 may be disposed on/in the front side surface 117 of the first semiconductor substrate 101. The first device level 103 may include a plurality of devices, which may include active devices, passive devices, or a combination thereof. In some embodiments, the devices in the first device level 103 may include integrated circuit devices. The devices may be, for example, transistors (e.g., field-effect transistors (FETs)), capacitors, resistors, diodes, photodiodes, fuse devices, or other similar devices. In some embodiments, the first device level 103 may include gate electrodes, source/drain regions, spacers, and the like.

The first semiconductor die 100 may also include a first interconnect structure located over the first device level 103 on the front side surface 117 of the first semiconductor substrate 101. The first interconnect structure may include first metal features 105 formed within a first dielectric material 104. The first dielectric material 104 may include one or more layers of dielectric material, such as at least one inter-layer dielectric (ILD) layer and/or at least one inter-metal dielectric (IMD) layer. The one or more layers of first dielectric material 104 may be formed of suitable dielectric materials such as silicon oxide (SiO₂) silicon nitride (SiN, Si₃N₄), silicon carbide (SiC), silicon oxynitride, or the like. Other dielectric materials are within the contemplated scope of disclosure. The one or more layers of first dielectric material 104 may be deposited using any suitable deposition process. Herein, “suitable deposition processes” may include a chemical vapor deposition (CVD) process, a physical vapor deposition (PVD) process, an atomic layer deposition (ALD) process, a high density plasma CVD (HDPCVD) process, a low pressure CVD process, a metalorganic CVD (MOCVD) process, a plasma enhanced CVD (PECVD) process, a sputtering process, laser ablation, or the like.

In various embodiments, the first metal features 105 of the first interconnect structure may include a plurality of metal vias and metal lines extending within the first dielectric material 104. The first metal features 105 may be formed of any suitable electrically conductive material, such as copper (Cu), tungsten (W), and aluminum (Al), including alloys and combinations thereof. Other electrically conductive materials are within the contemplated scope of disclosure. In some embodiments, a barrier layer (not shown) may be disposed between the first metal features 105 and the first dielectric material 104 to prevent diffusion of the electrically conductive material of the first metal features 105 to surrounding features. The barrier layers may include Ta, TaN, Ti, TiN, CoW, or combinations thereof, for example. Other barrier layer materials are within the contemplated scope of disclosure. The first metal features 105 and the optional barrier layers may be formed using a suitable deposition process, such as, for example, physical vapor deposition (PVD), sputtering, chemical vapor deposition (CVD), atomic layer deposition (ALD), plasma-enhanced chemical vapor deposition (PECVD), electrochemical deposition (e.g., electroplating), or combinations thereof. The first metal features 105 of the first interconnect structure may be configured to route electrical signals to and from, and/or in between, various devices of the first device structure 100, some or all of which may be located on the first device layer 103. In addition, the first metal features 105 may route electrical signals to and from, and/or in between, various devices of the first device structure 100 to various devices of subsequently stacked device structures (e.g., second device structure 200). The first metal features 105 may include first top metal features 106 that are exposed in an upper surface of the first interconnect structure. The first top metal features 106 may include metal pads laterally surrounded by the first dielectric material 104. In some embodiments, the first top metal features 106 may form a periodic array of first top metal features 106 over the upper surface of the first interconnect structure of the first device structure 100.

In some embodiments, the first device structure 100 may be a semiconductor die. In other embodiments, the first device structure 100 may include a portion of the semiconductor substrate 101 (i.e., a semiconductor wafer) having first devices and a first interconnect structure formed thereon that may be subsequently singulated (e.g., diced) to form one or more semiconductor dies.

FIG. 2 is a vertical cross-sectional view of the first device structure 100 illustrating a first dielectric layer 107 formed over the first interconnect structure according to various embodiments of the present disclosure. The first dielectric layer 107 may include a suitable dielectric material, such as silicon oxide, silicon nitride, silicon carbide, silicon carbon nitride, silicon oxynitride, or the like, including various combinations thereof, and may be formed using a suitable deposition process as described above. In some embodiments described in further detail below, the first dielectric layer 107 may include a dielectric polymer material. The first dielectric layer 107 may have a planar upper surface, as shown in FIG. 2.

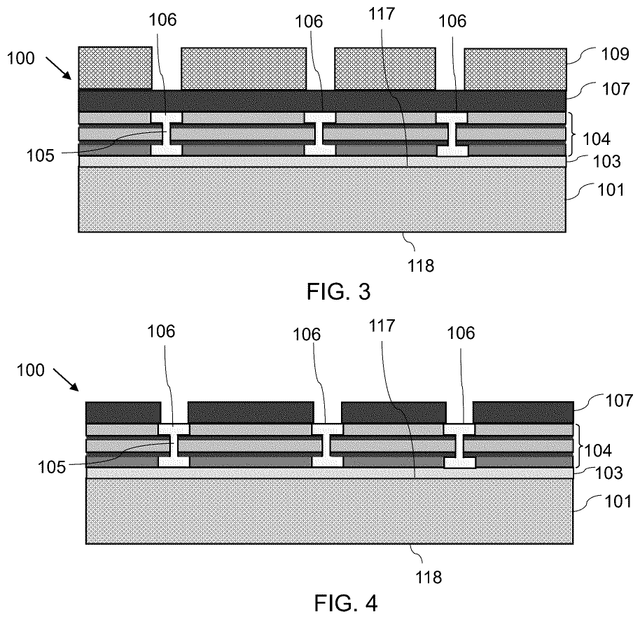

FIG. 3 is a vertical cross-sectional view of the first device structure 100 illustrating a patterned mask 109 formed over the upper surface of the first dielectric layer 107 according to various embodiments of the present disclosure. Referring to FIG. 3, the patterned mask 109, which may include a layer of photoresist and/or a hard mask, may be patterned using a photolithographic technique to form a plurality of openings through the mask 109. Each of the openings through the patterned mask 109 may overlie a respective first top metal feature 106 of the first interconnect structure of the first device structure 100.

FIG. 4 is a vertical cross-sectional view of the first device structure 100 illustrating a plurality of openings in the first dielectric layer 107 according to various embodiments of the present disclosure. Referring to FIG. 4, an anisotropic etch process, such as a reactive ion etch process, may be performed to etch portions of the first dielectric layer 107 exposed through the opening in the patterned mask 109 and thereby form openings through the first dielectric layer 107. A first top metal feature 106 may be exposed at the bottom of each of the openings through the first dielectric layer 107. Following the etching process, the patterned mask 109 may be removed using a suitable process, such as via ashing or dissolution using a solvent.

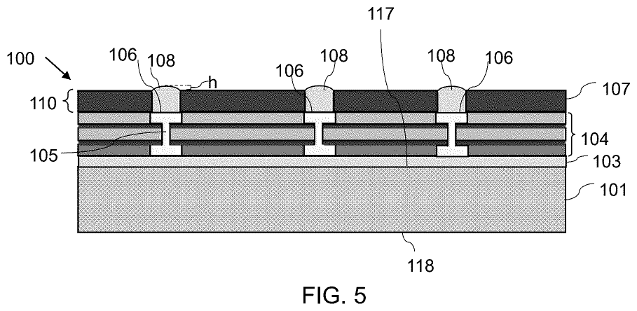

FIG. 5 is a vertical cross-sectional view of the first device structure 100 illustrating a plurality of first metal bonding structures 108 formed within the openings in the first dielectric layer 107 according to various embodiments of the present disclosure. Referring to FIG. 5, a metal material may be deposited over the exposed first top metal features 106 at the bottom of the openings through the first dielectric layer 107 using a suitable deposition process. In some embodiments, the metal material may be deposited using an electroless deposition process, as described in further detail below. The metal material may fill the volume of each of the openings through the first dielectric layer 107 to provide a plurality of first metal bonding structures 108 laterally surrounded by the first dielectric layer 107. The first metal bonding structures 108 may have convex upper surfaces, as shown in FIG. 5. The convex upper surfaces of each of the first metal bonding structures 108 may extend above the planar upper surface of the first dielectric layer 107 by a height, h. In some embodiments, the upper surfaces of the first metal bonding structures 108 may extend above the planar upper surface of the first dielectric layer 107 by a height, h, of at least about 1 nm.

Referring again to FIG. 5, the first dielectric layer 107 and the plurality of first metal bonding structures 108 may form a first bonding layer 110 of the first device structure 100. The first bonding layer 110 may be configured to enable bonding of the first device structure 100 to a second device structure to form a vertically stacked semiconductor device via a direct bonding technique, such as a metal-to-metal (M-M) and dielectric-to-dielectric (D-D) bonding technique.

In various embodiments, the first metal bonding structures 108 of the first bonding layer 110 may have a relatively lower density and a higher degree of compressibility (e.g., have a lower Young's modulus) than the metal bonding structures used in related direct bonding techniques. In some embodiments, the first metal bonding structures 108 having a relatively low density and high compressibility may be formed using an electroless deposition (ED) process. Electroless deposition is a process of depositing a material with the aid of a chemical reducing agent in a solution. The ED process is based on redox chemistry in which electrons are released from the reducing agent and metal ions (i.e., cations) within the solution are reduced to a metal or metal alloy that may be deposited on a target surface. The ED process is autocatalytic, meaning that the deposited metal material may function as a catalyst for further reduction reactions, enabling the deposition to continue in a self-sustaining manner. The ED process also does not require the application of external electrical power or current.

In various embodiments, surfaces of the first device structure 100 on which the metal bonding structures 108 are to be deposited (e.g., the exposed upper surfaces of the first top metal pads 106 and/or side surfaces of the first dielectric layer 107 within each of the openings through the first dielectric layer 107) may be pretreated (e.g., cleaned of contaminants) and optionally functionalized using a suitable catalyst (e.g., palladium). This may facilitate selective deposition of metal material within the openings through the first dielectric layer 107 with little to no deposition occurring in other regions of the first device structure 100, such as over the upper surface of the first dielectric layer 107. The first device structure 100 may be immersed in a solution (i.e., an ED bath) including suitable quantities of a reducing agent, a source of metal ions such as a metal salt, and optionally other constituents such as one or more complexing agents or stabilizers, pH adjustment buffer(s), and/or other suitable additives. Suitable reducing agents within the ED bath may include, without limitation, sodium hypophosphite, potassium hypophosphite, sodium borohydride, formaldehyde, hydrazine, dimethylamine borane, and the like. Other suitable reducing agents are within the contemplated scope of disclosure. Suitable sources of metal ions within the ED bath may include, without limitation, nickel chloride, copper sulfate, palladium chloride, gold cyanide, gold chloride, silver nitrate, and the like. Other suitable sources of metal ions are within the contemplated scope of disclosure.

The first device structure 100 may be maintained in the ED bath until a desired amount of metal material is deposited within the openings through the first dielectric layer 107. In some embodiments, the deposited metal material may fill the entire volume of each of the openings through the first dielectric layer 107 such that upper surfaces of the first metal bonding structures 108 may be coplanar with, or may extend above, the upper surface of the first dielectric layer 107. In various embodiments, each of the first metal bonding structures 108 may include a convex upper surface that extends above the plane of the upper surface of the first dielectric layer 107 by at least about 1 nm, as shown in FIG. 5. Since the first metal bonding structures 108 may be selectively deposited within the openings through the first dielectric layer 107, a planarization process, such as a chemical mechanical planarization (CMP) process, may not be required to remove excess metal material from over the upper surface of the first dielectric layer 107. This may be in contrast to related metal bonding structures that are formed using an electroplating deposition process in which a planarization step is typically required to remove excess metal material. However, such a planarization process may result in excess “dishing” of the metal bonding structures (i.e., such that portions of the metal bonding structures may be recessed relative to the upper surface of the first dielectric layer 107), which may increase the risk of metal disconnection defects occurring during the subsequent bonding of the first device structure 100 to a second device structure. In contrast, the first metal bonding structures 108 according to various embodiments of the present disclosure may extend to or above the plane of the upper surface of the first dielectric layer 107, which may help to ensure good metal-to-metal contact and mitigate against metal disconnection defects occurring during the subsequent bonding process.

The metal bonding structures 108 formed by ED may include a suitable metal material, such as copper, gold, silver, nickel, platinum, palladium, etc., including combinations and alloys thereof. Other suitable metal materials are within the contemplated scope of disclosure. In one non-limiting embodiment, the metal bonding structures 108 may include a gold/copper alloy surface finish to inhibit oxidation. The metal bonding structures 108 may additionally include one or more non-metallic elements, such as boron, phosphorus and/or sulfur. Such non-metallic elements may derive from the reducing agent(s) utilized in the ED bath solution and may become incorporated in the coating deposited on the target surface. In some embodiments, the metal bonding structure 108 may include at least about 1 at % (e.g., ˜1 at % to ˜35 at %) of a non-metallic component, such as boron, phosphorous and/or sulfur, including oxides thereof.

In various embodiments, the first metal bonding structures 108 formed by an ED process may have a lower density than metal bonding structures used in related direct bonding techniques that are formed using an electroplating deposition process. This may be due to a looser structure of the metal material formed by an ED process resulting from trapped impurities and vacancies. For example, a copper first metal bonding structure 108 formed by an ED process may have a density between about 8.76 g/cm³ and about 8.86 g/cm³ as compared with a density of about 8.96 g/cm³ for an equivalent copper bonding structure formed by an electroplating deposition process. In another example, a nickel first metal bonding structure 108 formed by an ED process may have a density between about 7.75 g/cm³ and about 8.5 g/cm³ as compared with a density of about 8.91 g/cm³ for an equivalent nickel bonding structure 108 formed by an electroplating deposition process. In general, the first metal bonding structures 108 formed by an ED process according to various embodiments may have a density that is less than the density of an equivalent metal bonding structure formed by an electroplating deposition process by at least about 1%, including by at least about 2%, by at least about 4%, or by at least about 10%. The lower density of the first metal bonding structures 108 according to various embodiments may provide a greater degree of compressibility. Thus, during the subsequent bonding process, mating pairs of metal bonding structures 108 may have a degree of compliance that may enable effective metal-to-metal and dielectric-to-dielectric contact without inducing high stress at the metal-to-metal interfaces, thereby reducing the risk of delamination defects occurring during the bonding process.

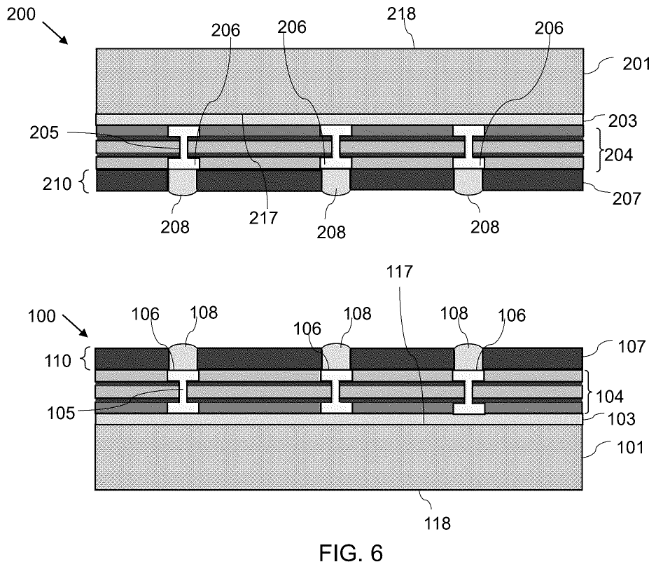

FIG. 6 is a vertical cross-sectional view illustrating a second device structure 200 aligned over the first device structure 100 according to an embodiment of the present disclosure. In the embodiment illustrated in FIG. 6, the second device structure 200 is a semiconductor die, although it will be understood that in other embodiments the second device structure 200 may be another structure, such as a semiconductor wafer. The second device structure 200 may have a similar structure as the first device structure 100. The second device structure 200 may include a second semiconductor substrate 201. The second semiconductor substrate 201 may be composed of the same semiconductor material as the first semiconductor substrate 101, or it may be composed of a different semiconductor material. The second semiconductor substrate 201 may include a first major surface (i.e., a front side surface 217) and a second major surface (i.e., a backside surface 218). A second device level 203 may be disposed on/in the front side surface 217 of the second semiconductor substrate 201, and a second interconnect structure including second metal features 205 (e.g., metal lines and vias) and second top metal features 106 embedded in a second dielectric material 204, may be located over the second device level 203. The second device level 203 and the second interconnect structure of the second device structure 200 may be similar to the first device level 103 and the first interconnect structure of the first device structure 100 described above with reference to FIG. 1. Thus, repeated discussion of like components is omitted for brevity.

The second device structure 200 may also include second bonding features disposed over the front side surface 217 of the second device structure 200. In the embodiment second device structure 200 shown in FIG. 6, the second bonding features include a second bonding layer 210 over the second interconnect structure. As with the first bonding layer 110 described above, the second bonding layer 210 may include plurality of second metal bonding structures 208 laterally surrounded by a second dielectric layer 207. The second metal bonding structures 208 may have a similar or identical construction as the first metal bonding structures 108 described above with reference to FIG. 5. Thus, repeated discussion of like features is omitted for brevity. In some embodiments, the second metal bonding structures 208 may be formed using an electroless deposition (ED) process. The arrangement of the second metal bonding structures 208 in the second bonding layer 210 may correspond to the arrangement of the first metal bonding structures 108 in the first bonding layer 110. In the embodiment of FIG. 6, the second metal bonding structures 208 of the second bonding layer 210 may have the same size and shape as the first metal bonding structures 108 of the first bonding layer 110. The second bonding layer 210 may be configured to enable a metal-to-metal (M-M) and dielectric-to-dielectric (D-D) direct bonding between the second bonding layer 210 of the second device structure 200 and the first bonding layer 110 of the first device structure 100 and thereby bond the second device structure 200 and the first device structure 100 to form a vertically stacked semiconductor device.

Referring again to FIG. 6, the first device structure 100 and the second device structure 200 may be aligned in a “face-to-face” orientation such that the bonding layer 110 of the first device structure 100 may face the bonding layer 210 of the second device structure 200. Each of the first metal bonding structures 108 of the first bonding layer 110 may be aligned with a corresponding second metal bonding structure 208 of the second bonding layer 210. In some embodiments, the surfaces of the first bonding layer 110 on the first device structure 100 and/or the second bonding layer 210 on the second device structure 200 may optionally be subjected to a pre-treatment process (e.g., a plasma treatment process) to promote surface activation of the first bonding layer 110 and/or the second bonding layer 210 prior to bonding the first device structure 100 to the second device structure 200.

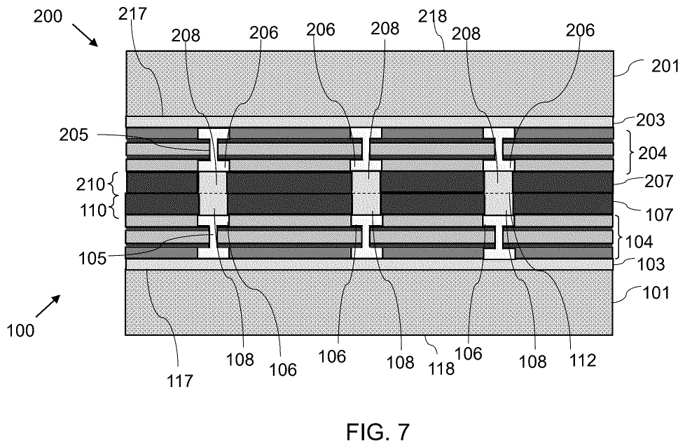

FIG. 7 is a vertical cross-sectional view illustrating the second device structure 200 placed onto the first device structure 100 according to various embodiments of the present disclosure. In various embodiments, the second device structure 200 and the first device structure 100 may be brought together such that the first bonding layer 110 of the first device structure 100 contacts the second bonding layer 210 of the second device structure 200. The second device structure 200 may be aligned over the front surface of the first device structure 100 such that the second metal bonding structures 208 of the second bonding layer 210 of the second device structure 200 contact corresponding first metal bonding structures 108 of the first bonding layer 110 of the first device structure 100 and the surface of the second dielectric layer 207 of the second bonding layer 210 of the second device structure 200 contacts the surface of the first dielectric layer 107 of the first bonding layer 110 of the first device structure 100.

Referring again to FIG. 7, in a direct bonding process, such as a metal-to-metal (M-M) and dielectric-to-dielectric (D-D) bonding process, bringing the second bonding layer 210 of the second device structure 200 into contact with the first bonding layer 110 of the first device structure 100 may result in a pre-bonding process in which chemical bonds (e.g., hydrogen bridge bonds) may form at the planar interface between the second dielectric layer 207 of the second bonding layer 210 and the first dielectric layer 107 of the first bonding layer 110. In some embodiments, the pre-bonding process may be performed at ambient temperature (e.g., ˜20° C.). In other embodiments, the pre-bonding process may be performed at an elevated temperature. In some embodiments, a compressive force may be applied to the first device structure 100 and the second device structure 200 during the pre-bonding process. In other embodiments, no compressive force may be applied during the pre-bonding process.

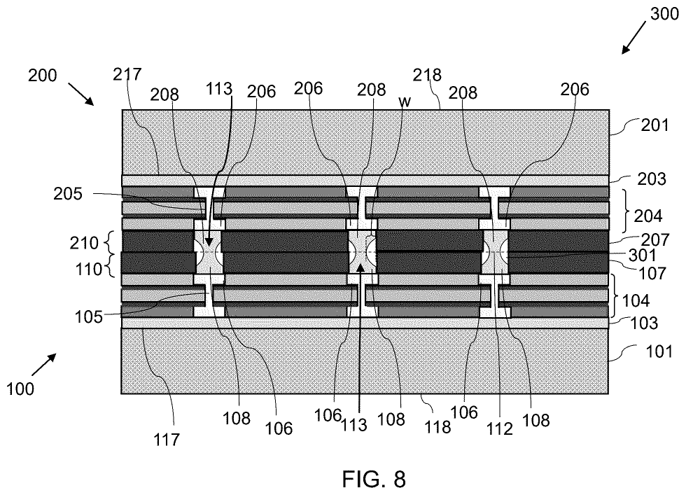

FIG. 8 is a vertical cross-sectional view illustrating a vertically stacked semiconductor device 300 following an annealing process that completes the bonding of the first metal bonding structures 108 of the first bonding layer 110 to the second metal bonding structures 208 of the second bonding layer 210 according to various embodiments of the present disclosure. Referring to FIG. 8, the first device structure 100 and the second device structure 200 may be subjected to an annealing process at an elevated temperature while the first bonding layer 110 of the first device structure 100 contacts the second bonding layer 210 of the second device structure 200. In some embodiments, a peak temperature of the annealing process may be between about 250° C. and about 350° C., although lower and higher temperatures may also be utilized. In some embodiments, a compressive force may be applied to the first device structure 100 and the second device structure 200 during the annealing process. In other embodiments, no compressive force may be applied during the annealing process.

In various embodiments, the annealing process may promote interdiffusion of the metal materials at the interface 112 between the first metal bonding structures 108 of the first bonding layer 110 and the corresponding second metal bonding structures 208 of the second bonding layer 210, thereby forming a plurality of metal bonds 113 that mechanically and electrically couple the first device structure 100 to the second device structure 200 to provide a vertically stacked semiconductor device 300. Each of the metal bonds 113 may include a suitable metallic material and may also include at least about 1 at % (e.g., ˜1 at % to ˜35 at %) of a non-metallic component, such as boron, phosphorous and/or sulfur, including oxides thereof. The annealing process may also induce recrystallization of the metal material of the first metal bonding structures 108 and the second metal bonding structures 208 that may result in shrinkage of the first metal bonding structures 108 and the second metal bonding structures 208. Following the annealing process, the first metal bonding structures 108 and the second metal bonding structures 208 may have an increased density and may be less compressible (i.e., have a higher Young's modulus) than prior to the annealing process. In some embodiments, the Young's modulus of the first metal bonding structures 108 and/or the second metal bonding structures 208 may increase by at least about 5%, including by at least about 8%, at by least about 10%, or by at least about 15% during the annealing process.

Following the annealing process, void areas 301 may be present between the metal bonds 113 and the side surfaces of the first dielectric layer 107 and the second dielectric layer 207 that laterally surround the metal bonds 113, as shown in FIG. 8. The void areas 301 may form due to the above-described shrinkage of the material of the first metal bonding structures 108 and the second metal bonding structures 208 during the annealing process. In some embodiments, a maximum width w of the void areas 301 between the metal bonds 113 and the surrounding side surfaces of the first dielectric layer 107 and/or the second dielectric layer 207 may be at least about 100 nm. The void areas 301 may be located adjacent to the planar interface between the first dielectric layer 107 of the first bonding layer 110 and the second dielectric layer 107 of the second bonding layer 210.

Following the bonding of the first device structure 100 to the second device structure 200 to form a vertically stacked semiconductor device 300, additional operations may be performed, such as thinning the back side surface(s) 118, 218 of the first semiconductor substrate 101 and/or the second semiconductor substrate 201 to expose through-substrate vias (TSVs) (not shown in FIG. 8), forming an interconnect layer including a dielectric material and metal features over the backside surface(s) 118, 218 of the first semiconductor substrate 101 and/or the second semiconductor substrate 201, and forming bonding features (e.g., metal bond pads) over the interconnect layer that are electrically coupled to the TSVs via the metal features of the interconnect layer.

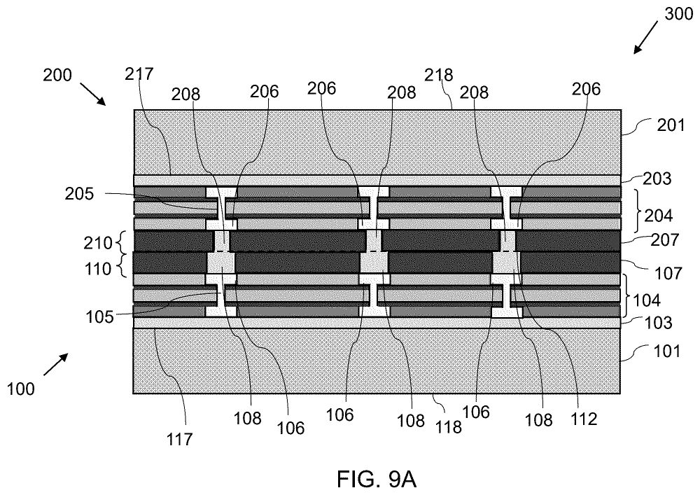

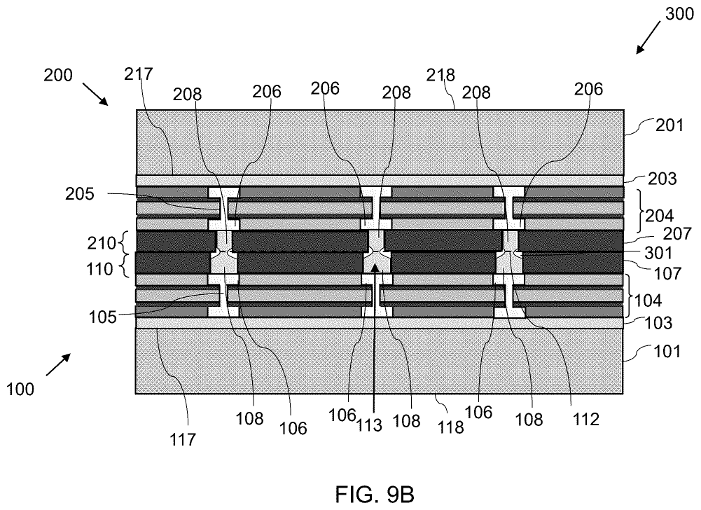

FIG. 9A is a vertical cross-sectional view illustrating a second device structure 200 placed onto a first device structure 100 according to another embodiment of the present disclosure. The first device structure 100 and the second device structure 200 shown in FIG. 9A are similar to first device structure 100 and the second device structure 200 described above with reference to FIG. 7. Thus, repeated discussion of like components is omitted for brevity. The first device structure 100 and the second device structure 200 of FIG. 9A differ from the first device structure 100 and the second device structure 200 shown in FIG. 7 in that the first bonding layer 110 and the second bonding layer 210 have different structures. In particular, the width of each of the second metal bonding structures 208 in the second bonding layer 210 may be less than the widths of the first metal bonding structures 108 in the first bonding layer 110. The second device structure 200 may be brought into contact with the first device structure 100 such that the second bonding layer 210 contacts the first bonding layer 110, as described above with reference to FIG. 7. The second dielectric layer 207 of the second bonding layer 210 may contact the first dielectric layer 107 of the first bonding layer 110. Each of the second metal bonding structures 208 of the second bonding layer 210 may contact a corresponding first metal bonding structure 108 of the first bonding layer 110. Portions of the first metal bonding structures 108 of the first bonding layer 110 may additionally contact regions of the second dielectric layer 207 surrounding the second metal bonding structures 208.

FIG. 9B is a vertical cross-sectional view illustrating a vertically stacked semiconductor device 300 following an annealing process that completes the bonding of the first metal bonding structures 108 of the first bonding layer 110 to the second metal bonding structures 208 of the second bonding layer 210 according to various embodiments of the present disclosure. Referring to FIG. 9B, an annealing process as described above with reference to FIG. 8 may be performed to form a plurality of metal bonds 113 mechanically and electrically coupling the first device structure 100 to the second device structure 200 to provide a vertically stacked semiconductor device 300. The portions of the metal bonds 113 adjacent to the first top metal pads 106 of the first interconnect structure of the first device structure 100 may have a width that is greater than the width of the portions of the metal pads 113 adjacent to the second top metal pads 106 of the second interconnect structure of the second device structure 200. Shrinkage of the metal materials of the first metal bonding structures 108 and the second metal bonding structures 208 may result in void areas 301 being present between the metal bonds 113 and the side surfaces of the first dielectric layer 107 and the second dielectric layer 207 that laterally surround the metal bonds 113, as shown in FIG. 9B. In some embodiments, a maximum width of the void areas 301 between the metal bonds 113 and the surrounding side surfaces of the first dielectric layer 107 and/or the second dielectric layer 207 may be at least about 100 nm. The void areas 301 may be located adjacent to the planar interface between the first dielectric layer 107 and the second dielectric layer 207. In the embodiment of FIG. 9B, the void areas 301 may also expose horizontally extending surfaces of the second dielectric layer 207 that were in contact with the first metal bonding structures 108 prior to the annealing process.

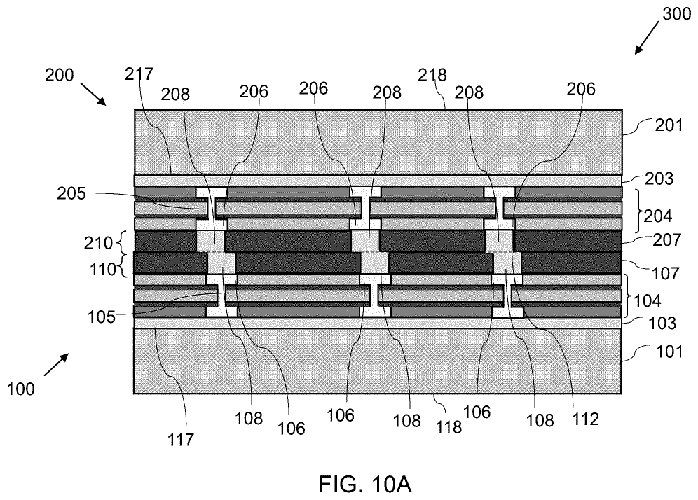

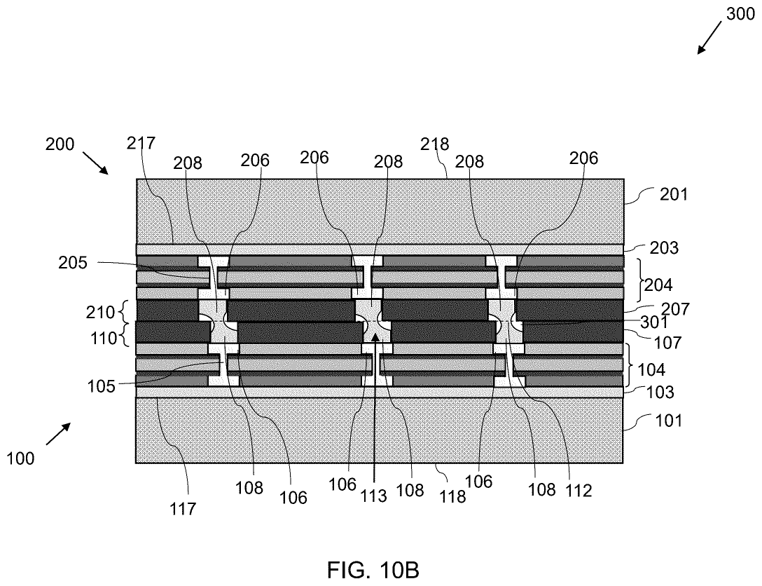

FIG. 10A is a vertical cross-sectional view illustrating a second device structure 200 placed onto a first device structure 100 according to another embodiment of the present disclosure. The first device structure 100 and the second device structure 200 shown in FIG. 10A are similar to first device structure 100 and the second device structure 200 described above with reference to FIG. 7. Thus, repeated discussion of like components is omitted for brevity. The first device structure 100 and the second device structure 200 of FIG. 10A differ from the first device structure 100 and the second device structure 200 shown in FIG. 7 in that the first metal bonding structures 108 of the first bonding layer 110 may be laterally offset from the second metal bonding structures 208 of the second bonding layer 210. The second device structure 200 may be brought into contact with the first device structure 100 such that the second bonding layer 210 contacts the first bonding layer 110, as described above with reference to FIG. 7. The second dielectric layer 207 of the second bonding layer 210 may contact the first dielectric layer 107 of the first bonding layer 110. Each of the second metal bonding structures 208 may contact a portion of a first metal bonding structure 108 and a portion of the first dielectric layer 107. Each of the first metal bonding structures 108 may contact a portion of a second metal bonding structure 208 and a portion of the second dielectric layer 207.

FIG. 10B is a vertical cross-sectional view illustrating a vertically stacked semiconductor device 300 following an annealing process that may complete the bonding of the first metal bonding structures 108 of the first bonding layer 110 to the second metal bonding structures 208 of the second bonding layer 210 according to various embodiments of the present disclosure. Referring to FIG. 10B, an annealing process as described above with reference to FIG. 8 may be performed to form a plurality of metal bonds 113 mechanically and electrically coupling the first device structure 100 to the second device structure 200 to provide a vertically stacked semiconductor device 300. The metal bonds 113 may extend at an oblique angle with respect to the planar interface between the first dielectric layer 107 and the second dielectric layer 207. Shrinkage of the metal materials of the first metal bonding structures 108 and the second metal bonding structures 208 may result in void areas 301 being present between the metal bonds 113 and the side surfaces of the first dielectric layer 107 and the second dielectric layer 207 that laterally surround the metal bonds 113, as shown in FIG. 10B. In some embodiments, a maximum width of the void areas 301 between the metal bonds 113 and the surrounding side surfaces of the first dielectric layer 107 and/or the second dielectric layer 207 may be at least about 100 nm. The void areas 301 may be located adjacent to the planar interface between the first dielectric layer 107 and the second dielectric layer 107. In the embodiment of FIG. 10B, the void areas 301 may also expose horizontally extending surfaces of the second dielectric layer 207 that were in contact with the first metal bonding structures 108 prior to the annealing process in addition to horizontally extending portions of the first dielectric layer 107 that were in contact with the second metal bonding structures 208 prior to the annealing process.

Although the embodiment of FIGS. 10A and 10B shows that the laterally-offset first metal bonding structures 108 and second metal bonding structures 208 have the same size and shape, it will be understood that the first metal bonding structures 108 and second metal bonding structures 208 may have different sizes and/or shapes. For example, the widths of the first metal bonding structures 108 may not be equal to the widths of the second metal bonding structures 208, as is shown in FIGS. 9A and 9B.

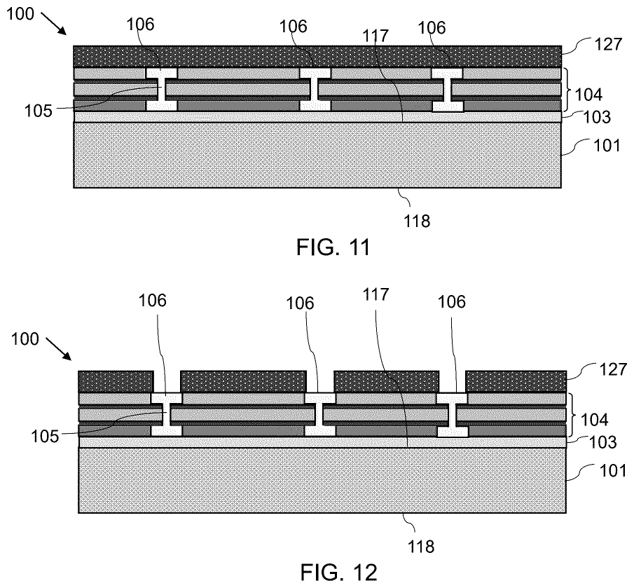

FIGS. 11-15 are sequential vertical cross-sectional views illustrating the intermediate structures during a process of fabricating a vertically stacked semiconductor device according to another embodiment of the present disclosure. FIG. 11 is a vertical cross-sectional view illustrating a first device structure 100 including a first interconnect structure and a first dielectric layer 127 formed over the first interconnect structure according to various embodiments of the present disclosure. The first device structure 100 of FIG. 11 may be similar to the first device structure 100 described above with reference to FIG. 2. Thus, repeated discussion of like features is omitted for brevity. The first device structure 100 of FIG. 11 may differ from the first device structure 100 of FIG. 2 in that the first dielectric layer 127 formed over the first interconnect structure includes a dielectric polymer material. Suitable dielectric polymer materials for the first dielectric layer 127 may include, for example, benzocyclobutene (BCB), parylene, and/or polyimide. Other suitable dielectric polymer materials are within the contemplated scope of disclosure. The first dielectric layer 127 may be formed using a suitable deposition process, such as spin coating, screen printing, spray coating, lamination, chemical vapor deposition (CVD), or the like. The first dielectric layer 127 including a dielectric polymer material may have a planar upper surface.

FIG. 12 is a vertical cross-sectional view of the first device structure 100 illustrating a plurality of openings in the first dielectric layer 127 according to various embodiments of the present disclosure. Referring to FIG. 12, a plurality of openings may be formed through the first dielectric layer 127. Each of the openings may correspond to the location of a first metal bonding structure to be subsequently formed. A first top metal feature 106 may be exposed at the bottom of each of the openings through the first dielectric layer 127.

In embodiments in which the first dielectric layer 127 is composed of a photosensitive (i.e., photoimageable) dielectric polymer material, such as a benzocyclobutene (BCB), parylene, and/or polyimide material, the openings through the first dielectric layer 127 may be formed using a photolithographic process. In one non-limiting example, a continuous layer 127 of a photosensitive dielectric polymer material may be coated or deposited over the first interconnect structure of the first device structure 100. Selected portions of the photosensitive dielectric polymer material may be exposed to optical radiation (e.g., UV radiation) through a patterned mask. Exposure to optical radiation may chemically alter the photosensitive dielectric polymer material by making the portions of the photosensitive dielectric polymer material that are exposed through the mask either more or less soluble relative to the surrounding material that is not exposed to optical radiation. Thus, by selectively exposing portions of the photosensitive dielectric polymer material to optical radiation through a patterned mask, the mask pattern may be transferred to the photosensitive dielectric polymer material. A developing process may be used to remove the more soluble portions of the photosensitive dielectric polymer material to provide a plurality of openings through the first dielectric layer 127. Other suitable methods for forming the plurality of openings through the first dielectric layer 127 may be utilized, such as a laser drilling process, an etching process through a lithographically-patterned mask, or the like. In some embodiments, the first dielectric layer 127 may include a dielectric polymer material that is not photosensitive.

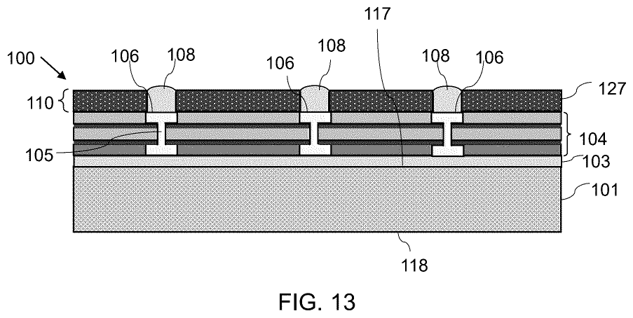

FIG. 13 is a vertical cross-sectional view of the first device structure 100 illustrating a plurality of first metal bonding structures 108 formed within the openings in the first dielectric layer 127 according to various embodiments of the present disclosure. The first metal bonding structures 108 of FIG. 13 may have a similar or identical construction and may be formed using similar or identical methods as the first metal bonding structures 108 described above with reference to FIG. 5. Thus, repeated discussion of like features is omitted for brevity. In various embodiments, the first metal bonding structures 108 may include a low-density, high-compressibility metal material that may be deposited using an electroless deposition (ED) process as described above.

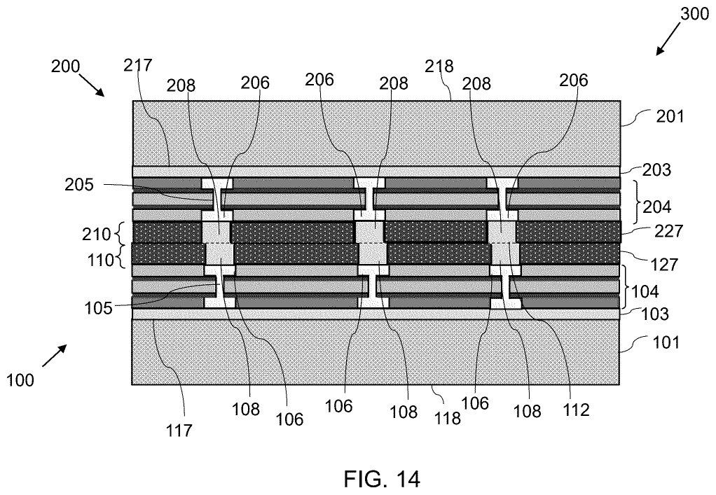

FIG. 14 is a vertical cross-sectional view illustrating a second device structure 200 placed onto the first device structure 100 according to various embodiments of the present disclosure. In the embodiment of FIG. 14, the second device structure 200 is a semiconductor die, although it will be understood that in other embodiments the second device structure 200 may be another structure, such as a semiconductor wafer. The second device structure 200 may have a similar structure as the first device structure 100 and may include a second semiconductor substrate 201, a second device level 203 disposed on/in the front side surface 217 of the second semiconductor substrate 201, a second interconnect structure including second metal features 205 (e.g., metal lines and vias) and second top metal features 206 embedded in a second dielectric material 204, and a second bonding layer 210 over the second interconnect structure. The second bonding layer 210 may include plurality of second metal bonding structures 208 laterally surrounded by a second dielectric layer 227. The second metal bonding structures 208 may have a similar or identical construction as the first metal bonding structures 108 in the first bonding layer 110 of the first device structure 100. In some embodiments, the second dielectric layer 227 of the second bonding layer 210 may include a dielectric polymer material as described above with reference to FIG. 11.

Referring again to FIG. 14, the second device structure 200 and the first device structure 100 may be brought together such that the first bonding layer 110 of the first device structure 100 contacts the second bonding layer 210 of the second device structure 200. The second device structure 200 may be aligned over the front surface of the first device structure 100 such that the second metal bonding structures 208 of the second bonding layer 210 of the second device structure 200 contact corresponding first metal bonding structures 108 of the first bonding layer 110 of the first device structure 100 and the surface of the second dielectric layer 227 of the second bonding layer 210 of the second device structure 200 contacts the surface of the first dielectric layer 127 of the first bonding layer 110 of the first device structure 100. As described above with reference to FIG. 7, bringing the second bonding layer 210 of the second device structure 200 into contact with the first bonding layer 110 of the first device structure 100 may result in a pre-bonding process in which chemical bonds (e.g., hydrogen bridge bonds) may form at the planar interface between the second dielectric layer 227 of the second bonding layer 210 and the first dielectric layer 127 of the first bonding layer 110. In some embodiments, the pre-bonding process may be performed at ambient temperature (e.g., ˜20° C.). In other embodiments, the pre-bonding process may be performed at an elevated temperature. In some embodiments, a compressive force may be applied to the first device structure 100 and the second device structure 200 during the pre-bonding process. In other embodiments, no compressive force may be applied during the pre-bonding process.

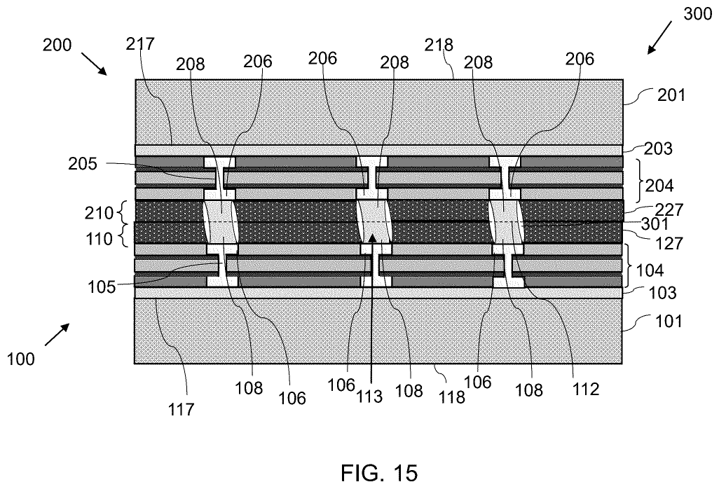

FIG. 15 is a vertical cross-sectional view illustrating a vertically stacked semiconductor device 300 following an annealing process that bonds the first metal bonding structures 108 of the first bonding layer 110 to the second metal bonding structures 208 of the second bonding layer 210 according to various embodiments of the present disclosure. Referring to FIG. 15, an annealing process as described above with reference to FIG. 8 may be performed to form a plurality of metal bonds 113 mechanically and electrically coupling the first device structure 100 to the second device structure 200 to provide a vertically stacked semiconductor device 300. Shrinkage of the metal materials of the first metal bonding structures 108 and the second metal bonding structures 208 may result in void areas 301 being present between the metal bonds 113 and the side surfaces of the first dielectric layer 127 and the second dielectric layer 127 that laterally surround the metal bonds 113, as shown in FIG. 15. In some embodiments, a maximum width of the void areas 301 between the metal bonds 113 and the surrounding side surfaces of the first dielectric layer 127 and/or the second dielectric layer 127 may be at least about 100 nm. The void areas 301 may be located adjacent to the planar interface between the first dielectric layer 127 and the second dielectric layer 227. In embodiments in which the first dielectric layer 127 and the second dielectric layer 227 include dielectric polymer materials, the annealing process may also result in shrinkage of the first dielectric layer 127 and the second dielectric layer 227. This may be due to cross-linking of functional groups of the dielectric polymer material(s) during the high-temperature annealing process that may form a tighter structure of the first dielectric layer 127 and the second dielectric layer 227. Accordingly, in some embodiments, each of the void areas 301 may be bounded by a first concave surface defined by the first dielectric layer 127 and the second dielectric layer 227 and a second concave surface defined by a respective metal bond 113, as shown in FIG. 15.

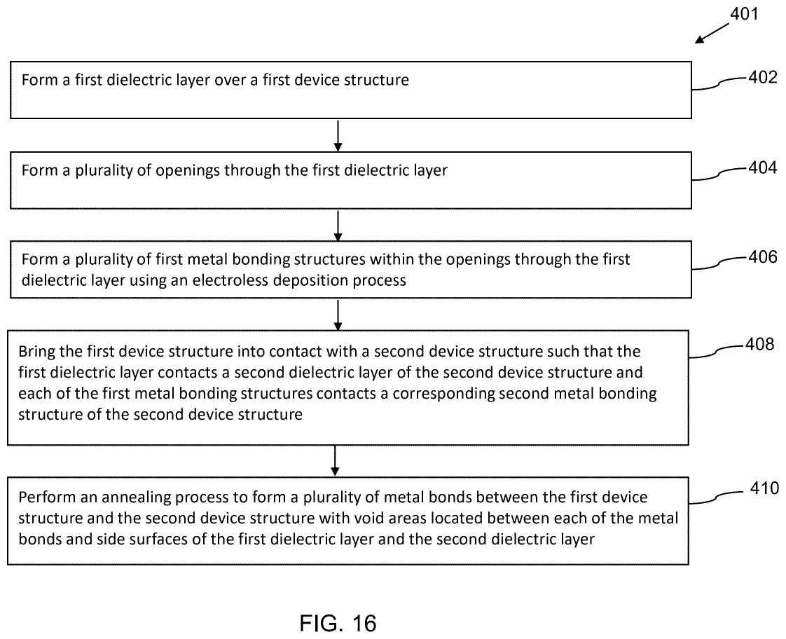

FIG. 16 is a flowchart illustrating a method 401 of fabricating a vertically stacked semiconductor device 300 according to an embodiment of the present disclosure. Referring to FIGS. 2, 11 and 16, in step 402 of method 401, a first dielectric layer 107, 127 may be formed over a first device structure 100. Referring to FIGS. 3, 4, 12 and 16, in step 404 of method 401, a plurality of openings may be formed through the first dielectric layer 107, 127. Referring to FIGS. 5, 13 and 16, in step 406 of method 401, a plurality of first metal bonding structures 108 may be formed within the openings through the first dielectric layer 107, 127 using an electroless deposition (ED) process. Referring to FIGS. 7, 9A, 10A, 14 and 16, in step 408 of method 401, the first device structure 100 may be brought into contact with a second device structure 200 such that the first dielectric layer 107, 127 contacts a second dielectric layer 207, 227 of the second device structure 200 and each of the first metal bonding structures 108 contacts a corresponding second metal bonding structure 208 of the second device structure 200. Referring to FIGS. 8, 9B, 10B, 15 and 16, in step 410 of method 401, an annealing process may be performed to form a plurality of metal bonds 113 between the first device structure 100 and the second device structure 200 with void areas 301 located between each of the metal bonds 113 and side surfaces of the first dielectric layer 107, 127 and the second dielectric layer 207, 227.

Referring to all drawings and according to various embodiments of the present disclosure, a semiconductor device 300 includes a first device structure 100 including a first semiconductor substrate 101, first devices, a first interconnect structure, and a first dielectric layer 107, 127, a second device structure 200 including a second semiconductor substrate 201, second devices, a second interconnect structure, and a second dielectric layer 207, 227, where the first dielectric layer 107, 127 contacts the second dielectric layer; 207, 227, and a plurality of metal bonds 113 extending between the first device structure 100 and the second device structure 200, where void areas 301 are located between each of the metal bonds 113 and side surfaces of the first dielectric layer 107, 127 and the second dielectric layer 207, 227.

In one embodiment, a maximum lateral width, w, of each of the void areas 301 is 100 nm or more. In another embodiment, each of the void areas 301 is adjacent to a planar interface between the first dielectric layer 107, 127 and the second dielectric layer 207, 227. In another embodiment, each of the metal bonds 113 extends between a first top metal pad 106 of the first interconnect structure and a second top metal pad 206 of the second interconnect structure. In another embodiment, a portion of each metal bond 113 located adjacent to a first top metal pad 106 has a width that is greater than the width of the portion of the metal bond 113 located adjacent to a second top metal pad 206, and a horizontal surface of the second dielectric layer 207, 227 extending parallel to the planar interface between the first dielectric layer 107, 127 and the second dielectric layer 207, 227 is exposed in each of the void areas 301. In another embodiment, each of the metal bonds extends between a first top metal pad 106 of the first interconnect structure and a second top metal pad 206 of the second interconnect structure at an oblique angle with respect to the planar interface between the first dielectric layer 107, 127 and the second dielectric layer 207, 227, and horizontal surfaces of the first dielectric layer 107, 127 and the second dielectric layer 207, 227 extending parallel to the planar interface between the first dielectric layer 107, 127 and the second dielectric layer 207, 227 are exposed in each of the void areas 301. In another embodiment, the first dielectric layer 107, 127 and the second dielectric layer 207, 227 include one or more of silicon oxide, silicon nitride, silicon carbide, silicon carbon nitride, and silicon oxynitride. In another embodiment, the first dielectric layer 107, 127 and the second dielectric layer 207, 227 include dielectric polymer materials. In another embodiment, each of the void areas 301 is bounded by a first concave surface defined by the first dielectric layer 107, 127 and the second dielectric layer 207, 227 and a second concave surface defined by a metal bond 113. In another embodiment, each of the metal bonds includes at least 1 at % of boron, phosphorous and/or sulfur, including oxides thereof.

Another embodiment is drawn to a semiconductor device 300 that includes a first device structure 100 including a first semiconductor substrate 101, first devices, a first interconnect structure, and a first dielectric layer 107, 127, a second device structure 200 including a second semiconductor substrate 201, second devices, a second interconnect structure, and a second dielectric layer 207, 227, where the first dielectric layer 107, 127 contacts the second dielectric layer 207, 227, and a plurality of metal bonds 113 extending between the first device structure 100 and the second device structure 200, where each of the metal bonds 113 includes at least 1 at % of boron, phosphorous and/or sulfur, including oxides thereof.

In one embodiment, the metal bonds 113 further include at least one of copper, gold, silver, nickel, platinum, and palladium. In another embodiment, the metal bonds 113 include a copper and gold alloy. Another embodiment is drawn to a method of fabricating a vertically stacked semiconductor device 300 that includes forming a first dielectric layer 107, 127 over a first device structure 100, forming a plurality of openings through the first dielectric layer 107, 127, forming a plurality of first metal bonding structures 108 within the openings through the first dielectric layer 107, 127 using an electroless deposition process, bringing the first device structure 100 into contact with a second device structure 100 such that the first dielectric layer 107, 127 contacts a second dielectric layer 207, 227 of the second device structure 200 and each of the first metal bonding structures 108 contacts a corresponding second metal bonding structure 208 of the second device structure 200, and performing an annealing process to promote interdiffusion between the first metal bonding structures 108 and the corresponding second metal bonding structures 208 and form a plurality of metal bonds 113 between the first device structure 100 and the second device structure 200 with void areas 301 located between each of the metal bonds 113 and side surfaces of the first dielectric layer 107, 127 and the second dielectric layer 207, 227. In one embodiment, forming the plurality of first metal bonding structures 108 includes forming first metal bonding structures 108 having a convex upper surface that extends above a plane of an upper surface of the first dielectric layer 107, 127 by 1 nm or more.

In another embodiment, prior to the annealing process, the plurality of first metal bonding structures 108 have a Young's modulus that is at least 5% less than the Young's modulus of the metal bonds 113 formed during the annealing process. In another embodiment, a maximum lateral width, w, of each of the void areas 301 is 100 nm or more. In another embodiment, each of the metal bonds 113 includes at least 1 at % of boron, phosphorous and/or sulfur, including oxides thereof. In another embodiment, the first dielectric layer 107, 127 includes a dielectric polymer material. In another embodiment, forming the plurality of openings through the first dielectric layer 107, 127 includes lithographically patterning the first dielectric layer 107, 127 by selectively exposing regions of the dielectric polymer material to optical radiation.

The foregoing outlines features of several embodiments so that those skilled in the art may better understand the aspects of this disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of this disclosure, and that they may make various changes, substitutions, and alterations herein without departing from the spirit and scope of the present disclosure.

What is claimed is:

1. A semiconductor device, comprising:
a first device structure comprising a first semiconductor substrate, first devices, a first interconnect structure, and a first dielectric layer;
a second device structure comprising a second semiconductor substrate, second devices, a second interconnect structure, and a second dielectric layer, wherein the first dielectric layer contacts the second dielectric layer; and
a plurality of metal bonds extending between the first device structure and the second device structure, wherein void areas are located between each of the metal bonds and side surfaces of the first dielectric layer and the second dielectric layer.

2. The semiconductor device of claim 1, wherein a maximum lateral width of each of the void areas is 100 nm or more.

3. The semiconductor device of claim 1, wherein each of the void areas is adjacent to a planar interface between the first dielectric layer and the second dielectric layer.

4. The semiconductor device of claim 3, wherein each of the metal bonds extends between a first top metal pad of the first interconnect structure and a second top metal pad of the second interconnect structure.

5. The semiconductor device of claim 4, wherein a portion of each metal bond located adjacent to a first top metal pad has a width that is greater than the width of the portion of the metal bond located adjacent to a second top metal pad, and a horizontal surface of the second dielectric layer extending parallel to the planar interface between the first dielectric layer and the second dielectric layer is exposed in each of the void areas.

6. The semiconductor device of claim 4, wherein each of the metal bonds extends between a first top metal pad of the first interconnect structure and a second top metal pad of the second interconnect structure at an oblique angle with respect to the planar interface between the first dielectric layer and the second dielectric layer, and horizontal surfaces of the first dielectric layer and the second dielectric layer extending parallel to the planar interface between the first dielectric layer and the second dielectric layer are exposed in each of the void areas.

7. The semiconductor device of claim 1, wherein the first dielectric layer and the second dielectric layer comprise one or more of silicon oxide, silicon nitride, silicon carbide, silicon carbon nitride, and silicon oxynitride.

8. The semiconductor device of claim 1, wherein the first dielectric layer and the second dielectric layer comprise dielectric polymer materials.

9. The semiconductor device of claim 8, wherein each of the void areas is bounded by a first concave surface defined by the first dielectric layer and the second dielectric layer and a second concave surface defined by a metal bond.

10. The semiconductor device of claim 1, wherein each of the metal bonds comprises at least 1 at % of boron, phosphorous and/or sulfur, including oxides thereof.

11. A semiconductor device, comprising:
a first device structure comprising a first semiconductor substrate, first devices, a first interconnect structure, and a first dielectric layer;
a second device structure comprising a second semiconductor substrate, second devices, a second interconnect structure, and a second dielectric layer, wherein the first dielectric layer contacts the second dielectric layer; and
a plurality of metal bonds extending between the first device structure and the second device structure, wherein each of the metal bonds comprises at least 1 at % of boron, phosphorous and/or sulfur, including oxides thereof.

12. The semiconductor device of claim 11, wherein the metal bonds further comprise at least one of copper, gold, silver, nickel, platinum, and palladium.

13. The semiconductor device of claim 12, wherein the metal bonds comprise a copper and gold alloy.

14. A method of fabricating a vertically stacked semiconductor device, comprising:
forming a first dielectric layer over a first device structure;
forming a plurality of openings through the first dielectric layer;
forming a plurality of first metal bonding structures within the openings through the first dielectric layer using an electroless deposition process;
bringing the first device structure into contact with a second device structure such that the first dielectric layer contacts a second dielectric layer of the second device structure and each of the first metal bonding structures contacts a corresponding second metal bonding structure of the second device structure; and
performing an annealing process to promote interdiffusion between the first metal bonding structures and the corresponding second metal bonding structures and form a plurality of metal bonds between the first device structure and the second device structure with void areas located between each of the metal bonds and side surfaces of the first dielectric layer and the second dielectric layer.

15. The method of claim 14, wherein forming the plurality of first metal bonding structures comprises forming first metal bonding structures having a convex upper surface that extends above a plane of an upper surface of the first dielectric layer by 1 nm or more.

16. The method of claim 14, wherein prior to the annealing process, the plurality of first metal bonding structures have a Young's modulus that is at least 5% less than the Young's modulus of the metal bonds formed during the annealing process.

17. The method of claim 14, wherein a maximum lateral width of each of the void areas is 100 nm or more.

18. The method of claim 14, wherein each of the metal bonds comprises at least 1 at % of boron, phosphorous and/or sulfur, including oxides thereof.

19. The method of claim 14, wherein the first dielectric layer comprises a dielectric polymer material.

20. The method of claim 19, wherein forming the plurality of openings through the first dielectric layer comprises lithographically patterning the first dielectric layer by selectively exposing regions of the dielectric polymer material to optical radiation.
